(19) United States
(12) Patent Application Publication
(10) Pub. No.: US 2026/0155818 A1
(43) Pub. Date: Jun. 4, 2026

(54) GATE DRIVE CIRCUIT

(71) Applicant: The Hong Kong Polytechnic University, HONG KONG (CN)

(72) Inventors: Wei Liu, HONG KONG (CN); Jian SONG, HONG KONG (CN); Tianyi LIU, HONG KONG (CN); Chang LIU, HONG KONG (CN); Kwok Tong Chau, HONG KONG (CN)

(73) Assignee: The Hong Kong Polytechnic University, HONG KONG (CN)

(21) Appl. No.: 19/359,619

(22) Filed: Oct. 15, 2025

Related U.S. Application Data
(60) Provisional application No. 63/726,890, filed on Dec. 2, 2024.

(51) Int. Cl. H03K 17/16; H03K 17/06; H03K 17/0812

(52) U.S. Cl. CPC H03K 17/163; H03K 17/063; H03K 17/08122; H03K 2217/0081

(57) ABSTRACT

A gate drive circuit for a half-bridge power module with a first and second GaN HEMT is disclosed. The circuit mitigates gate voltage overshoot, oscillation, and crosstalk induced by high dv/dt at the switching node. It includes a voltage clamp circuit, electrically connected to the gate of the first GaN HEMT, to suppress gate voltage overshoot. A negative voltage generation and control circuit is configured to generate and apply a negative voltage to the gate to offset positive crosstalk voltage spikes. A low-impedance Miller current path circuit is connected to the gate to provide a discharge path for Miller current, thereby suppressing negative crosstalk voltage spikes. The circuit provides robust protection for GaN HEMTs operating at high switching speeds.

### CROSS-REFERENCE TO RELATED APPLICATION

This application claims the priority benefit of U.S. Provisional Application 63/726,890, filed Dec. 2, 2024. The entirety of the above-mentioned patent application is hereby incorporated by reference herein and made a part of this specification.

### BACKGROUND

### Technical Field

The present disclosure relates primarily to driving technology for field-effect transistors. More particularly, the present disclosure relates to a gate drive circuit for gallium nitride (GaN) high electron mobility transistors (HEMTs).

### Description of Related Art

Among wide-bandgap semiconductor devices, GaN power devices exhibit advantages including low parasitic parameters, high switching speed, low on-resistance, and high electron mobility, thereby offering a superior solution for the design of high-frequency and high-power-density equipment such as wireless chargers, data center power supplies, and robotic power converters.

Conventional GaN HEMTs available on the market suffer from two inherent limitations: low threshold voltage and low gate withstand voltage. The low threshold voltage renders the devices susceptible to spurious turn-on induced by minor interference signals, while the low gate withstand voltage increases vulnerability to gate damage due to overvoltage breakdown. These limitations result in high sensitivity to interference in half-bridge converter applications. When GaN HEMTs operate at high voltages and high switching speeds, elevated dv/dt is generated at the switching node of the bridge arm. This high dv/dt, in turn, produces voltage overshoot as well as positive and negative crosstalk voltage spikes, which can lead to false triggering and breakdown of the GaN HEMTs.

Specifically, within a half-bridge circuit, when transistors switch at high speed, an extremely high rate of voltage change (dv/dt) occurs at the switching node (SW node). This rapidly changing voltage couples through the parasitic capacitance of the complementary transistor—primarily the Miller capacitance (Cgd)—disturbing the gate voltage of the off-state transistor and introducing two critical issues. First, positive crosstalk voltage spikes, which may cause spurious turn-on of the normally off transistor, resulting in shoot-through conditions, bridge-arm short-circuiting, and potential device failure. Second, negative crosstalk voltage spikes, which, although not causing unintended turn-on, can exceed the negative voltage rating of the gate and lead to gate dielectric breakdown.

Furthermore, due to the presence of parasitic inductances and capacitances, the gate loop itself is prone to voltage overshoot and oscillation, which may also exceed the safe operating voltage range of the device.

To facilitate broader application of GaN HEMTs, it is essential to address these crosstalk and overshoot challenges.

Currently, three conventional methods are predominantly employed to mitigate crosstalk and overshoot. The first approach involves reducing the dv/dt of the device by increasing the gate resistance or connecting an external capacitor between the gate and source terminals. However, this approach reduces the turn-on and turn-off speed of GaN HEMTs, limiting the device's capabilities in high-frequency applications. The second approach is to employ an isolated negative supply or charge pump, which generates a constant negative voltage to turn off the GaN HEMTs. The issue is that the constant negative voltage applied to the gate can cause more reverse conduction losses and increase the risk of the device reverse breakdown when negative crosstalk occurs. The third method is to provide a low-impedance path for crosstalk currents, which can effectively block the Miller current or reduce its amplitude. However, diode-based low-impedance paths need to be carefully designed for crosstalk phenomena.

Therefore, there is a need of a drive circuit capable of effectively resolving voltage overshoot and crosstalk issues in half-bridge power modules.

### SUMMARY

The present disclosure provides a gate drive circuit that can effectively reduce the overshoot and oscillation of the drive voltage caused by the parasitic stray inductance and solve both positive and negative crosstalk problems when the switching node of the bridge arm is at a high and fast change of dv/dt.

According to the first aspect of the present application, there is provided a gate drive circuit for a half-bridge power module having a first GaN HEMT and a second GaN HEMT, the gate drive circuit comprising: a voltage clamp circuit electrically connected to a gate of the first GaN HEMT for suppressing a gate voltage overshoot at the gate; a negative voltage generation and control circuit configured to generate a negative voltage and to apply the generated negative voltage to the gate of the first GaN HEMT to offset a positive crosstalk voltage spike at the gate; and a low-impedance Miller current path circuit connected to the gate of the first GaN HEMT and configured to provide a discharge path for a Miller current to suppress the negative crosstalk voltage spike.

In a preferred embodiment, the voltage clamp circuit is electrically connected between a gate control output of a first driver integrated circuit (IC) and a ground of the driver IC, and further between a gate resistor and a Kelvin source of the first GaN HEMT, wherein the Kelvin source is directly connected to the ground of the driver IC.

In a further preferred embodiment, the negative voltage generation and control circuit is in communication with a signal source to receive at least one control signal and is operably connected to the gate of the first GaN HEMT via the low-impedance Miller current path circuit.

In a further preferred embodiment, the low-impedance Miller current path circuit is electrically connected to the gate of the first GaN HEMT to receive the Miller current and to the ground to discharge the Miller current.

In a preferred embodiment, the voltage clamp circuit comprises a Zener diode having a cathode electrically connected to the gate control output of the driver IC; a first resistor having a first end connected to an anode of the Zener diode and a second end connected to a Kelvin source of the first GaN HEMT; and a first capacitor connected in parallel with the first resistor.

Preferably, the gate resistor has a first end connected to the cathode of the Zener diode and a second end connected to the gate of the first GaN HEMT.

In a preferred embodiment, the negative voltage generation and control circuit comprises an AND gate having a first input end and a second input end configured to receive control signals from a signal source; a negative voltage generation circuit having an input end connected to an output end of the AND gate and configured to generate the negative voltage; and a switching transistor having a gate connected to the output end of the AND gate, and configured to selectively apply the negative voltage to the gate of the first GaN HEMT.

In a further preferred embodiment, the negative voltage generation circuit comprises: a NOT gate having an input end connected to the output end of the AND gate; a second capacitor having a first end connected to an output end of the NOT gate; and a first diode having an anode connected to a second end of the second capacitor and a cathode connected to the ground.

In a further preferred embodiment, the switching transistor is a metal oxide semiconductor field effect transistor (MOSFET) having a gate connected to the output end of the AND gate, a drain connected to the gate of the first GaN HEMT via the low-impedance Miller current path circuit, and a source connected to the negative voltage generation circuit.

In a preferred embodiment, the low-impedance Miller current path circuit comprises a second diode connected in parallel with the gate resistor of the first GaN HEMT, a cathode of the second diode being connected to the gate of the first GaN HEMT; and a switching transistor configured to, when turned on, provide an electrical connection between an anode of the second diode and a ground. Preferably, the switching transistor is controlled by the negative voltage generation and control circuit.

In a further preferred embodiment, the switching transistor is a MOSFET having a gate connected to the output end of the AND gate, a drain connected to the gate resistor of the first GaN HEMT and the anode of the second diode, and a source connected to the ground.

In a preferred embodiment, the gate drive circuit further comprises an additional voltage clamp circuit electrically connected to a gate resistor of the second GaN HEMT for suppressing a gate voltage overshoot at the gate; an additional negative voltage generation and control circuit configured to generate a negative voltage and to apply the generated negative voltage to the gate of the second GaN HEMT to offset a positive crosstalk voltage spike at the gate; and an additional low-impedance Miller current path circuit connected to the gate of the second GaN HEMT and configured to provide a discharge path for a Miller current to suppress the negative crosstalk voltage spike; wherein the additional voltage clamp circuit has the same topology as the voltage clamp circuit; the additional negative voltage generation and control circuit has the same topology as the negative voltage generation and control circuit; the additional low-impedance Miller current has the same topology as the low-impedance Miller current.

Preferably, the Zener diode is a diode with an ultra-short reverse recovery time of less than 0.1 μs.

Preferably, the GaN HEMT is an E-mode GaN HEMT.

Preferably, the first capacitor has a capacitance value in a range of 1−100 nF.

Preferably, the gate resistor has a resistance value in a range of 1−100Ω.

Preferably, the E-mode GaN HEMT has a rated current higher than the current flowing through the gate drive circuit during the crosstalk event, e.g., 0.1 A.

Preferably, the AND gate is a high-frequency operating component, such as at 5 MHz.

Preferably, the logic NOT component is a high-frequency operating component, such as at 5 MHz.

Preferably, the MOSFET can be a positive metal oxide semiconductor (PMOS) or negative metal oxide semiconductor (NMOS), or can be replaced by silicon carbide (SiC) or GaN, which are high-frequency devices such as 5 MHz.

One objective of the proposed invention is to provide a voltage clamp circuit for GaN HEMTs. This clamp circuit can effectively reduce the overshoot and oscillation of the drive voltage caused by the parasitic stray inductance to realize the protection of the GaN HEMT gate, when it operates at high switching speeds. Another objective of the proposed invention is to provide a negative voltage generation and control circuit and a low-impedance Miller current path for GaN half-bridge modules. These measures can effectively solve both positive and negative crosstalk problems when the switching node of the bridge arm is at a high and fast change of dv/dt.

In one embodiment of the present invention, a voltage clamp circuit for GaN HEMT is designed. The GaN HEMT has a gate, a drain, a Kelvin source and a power source. The gate clamp circuit comprises: (1) the cathode of a Zener diode is connected to the first end of a gate resistor, while the second end of the gate resistor is connected to the gate of GaN HEMT; (2) the anode of the Zener diode is connected to the first end of another resistor, while the second end of the resistor is connected to the Kelvin source of GaN; (3) a capacitor is connected in parallel at both ends of the resistor. When the drive voltage overshoot occurs, the Zener diode enters a breakdown to stabilize the gate voltage for realizing overshoot protection of the gate.

In one embodiment of the present invention, a negative voltage generation and control circuit is proposed, which comprises: the inputs of an AND gate are the signals of the controller; the output of the AND gate is connected to the gate of the MOSFET; at the same time, its output is also connected to the input of the NOT gate; the output of the NOT gate is connected to the first end of a capacitor; the second end of the capacitor is connected to the anode of the ground diode in the low-impedance Miller current path.

In one embodiment of the present invention, a low-impedance Miller current path is designed. The low-impedance Miller current path comprises: the diode is connected in parallel with the gate resistor; its cathode is connected to the gate of GaN; its anode is connected to a drain of MOSFET; the source of MOSFET is connected to the anode of another diode; the cathode of the diode is connected to the ground of the driver IC. When crosstalk occurs and the crosstalk spike is greater than the diode's forward conduction voltage, the low-impedance Miller current path acts and absorbs the crosstalk spike.

In one embodiment of the present invention, when only control signal or logic components need to be changed, the MOSFET can be a positive metal oxide semiconductor (PMOS) or negative metal oxide semiconductor (NMOS), or can be replaced by silicon carbide (SiC) or GaN.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a circuit schematic diagram of a gate drive circuit for a GaN half-bridge power module in accordance with the present invention.

FIG. 2 shows an exemplary application circuit for a GaN half-bridge module.

FIG. 3 illustrates an operating principle of the voltage clamp circuit, using a voltage overshoot of a lower bridge arm as an example.

FIG. 4 illustrates an operating principle of the negative voltage generation and control circuit, using a positive crosstalk of a lower bridge arm as an example.

FIG. 5 illustrates an operating principle of the low-impedance Miller current path, using a negative crosstalk of a lower bridge arm as an example.

FIG. 6A, FIG. 6B, and FIG. 6C show voltage overshoot and crosstalk suppression results comparing the present invention with a conventional drive circuit.

### DESCRIPTION OF THE EMBODIMENTS

Detailed reference is now made to the embodiments of the present application, with the figures illustrating one or more embodiments. The repeated use of figure labels throughout this specification serves to indicate similar features or elements of the present application. The following content is provided to facilitate a further understanding of the present application for those skilled in the art but does not limit the application in any form. It should be noted that various modifications and changes can be made by those skilled in the art without departing from the concept of the present application. For example, features shown or described as part of one embodiment may be used in conjunction with another embodiment to generate further implementations. Consequently, the present application is intended to encompass such variations and changes within the scope of the appended claims and their equivalents.

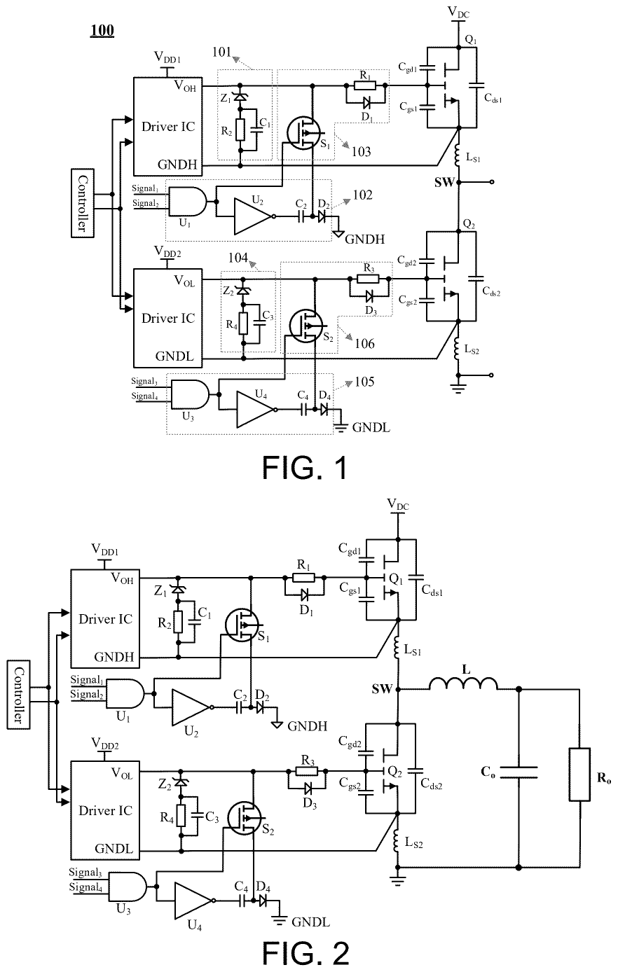

FIG. 1 illustrates a preferred embodiment of the present invention. Centrally located in FIG. 1 is a gate drive circuit 100 for a GaN half-bridge power module. Positioned to the left of the drive circuit are a controller and driver ICs, which provide driving control signals. Located to the right of the drive circuit is the GaN half-bridge power module.

The drive circuit 100 includes voltage clamp circuits 101 and 104, negative voltage generation and control circuits 102 and 105, and low-impedance Miller current paths 103 and 106. Since the drive circuits for the upper and lower bridge arms are substantially identical, the drive circuit for the lower bridge arm GaN is described in detail as an exemplary implementation.

The GaN HEMT Q₂ includes a gate, a drain, a Kelvin source, and a source terminal. A power output terminal of a driver and a ground terminal are provided. The voltage clamp circuit 104 is electrically connected between the gate control output terminal and ground terminal of the driver IC, and further between the gate resistor and the Kelvin source terminals of the second GaN HEMT.

The gate clamp circuit 104 comprises a core clamping component, namely a Zener diode Z₂; a current limiting and discharge resistor R₄; and an energy storage and filtering capacitor C₃. An gate control output terminal V_{OL} of the driver IC is connected to the cathode of Zener diode Z₂ in circuit 104, while a GNDL terminal is connected to capacitor C₃ in circuit 104. The cathode of Zener diode Z₂ is connected to a first end of a gate resistor R₃, a second end of which is connected to the gate of GaN HEMT Q₂. The anode of the Zener diode is connected to a first end of resistor R₄, a second end of which is connected to the Kelvin source of GaN HEMT Q₂. Capacitor C₃ is connected in parallel with resistor R₄.

The voltage clamp circuit 104 suppresses gate voltage overshoot and oscillation, thereby preventing the gate voltage from exceeding a safe operating voltage of the GaN device. When gate voltage overshoot occurs due to parasitic oscillation, the voltage reaches the breakdown voltage of the Zener diode Z₂. Zener diode Z₂ breaks down, thereby clamping the excessive voltage to its breakdown voltage level. Simultaneously, capacitor C₃ is charged through Zener diode Z₂, thereby absorbing energy from the overshoot. After the overshoot subsides, capacitor C₃ discharges gradually through resistor R₄. This circuit not only limits the maximum voltage amplitude but also dampens oscillations, thereby protecting the gate.

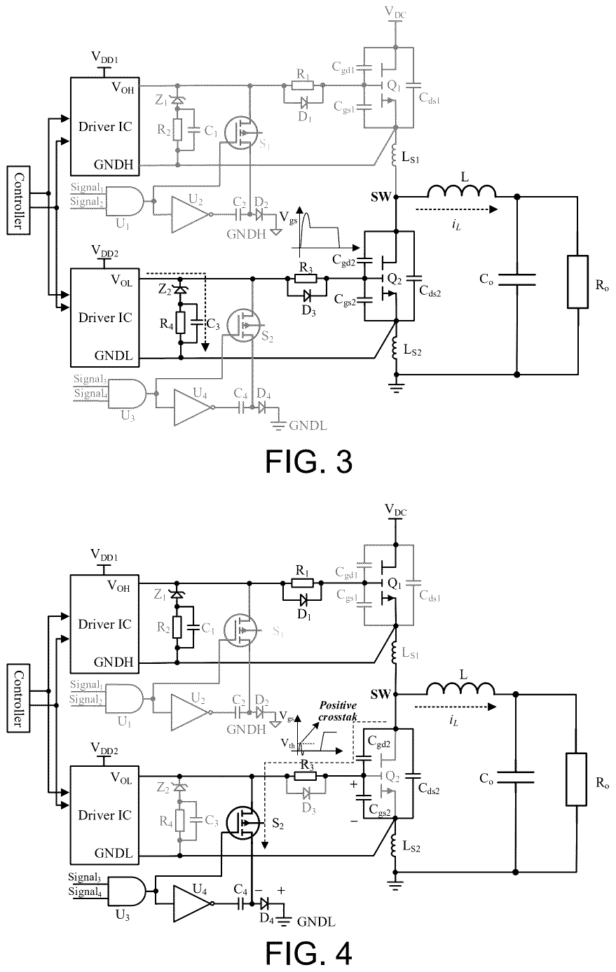

FIG. 3 illustrates the operating principle of the voltage clamp circuit, using a voltage overshoot in a lower bridge arm as an example. When Q₂ is undergoing a turn-on transition while Q₁ is turned off, the high switching speed of Q₂, in combination with effects of parasitic inductance and capacitance, can induce resonance in the gate loop of Q₂ (formed by V_{OL}−R₃/D₃−C_{gs2}−Lₛ₂), ultimately resulting in voltage overshoot and oscillation. Zener diode Z₂ breaks down, thereby stabilizing the gate voltage and charging capacitor C₃. After the voltage overshoot diminishes, capacitor C₃ discharges through resistor R₄. It is noteworthy that the breakdown of the Zener diode is reversible, thereby ensuring that the gate voltage remains within a safe operating range.

Under normal switching conditions, when the driver IC outputs a drive signal to perform switching operations, provided the steady-state gate voltage (V_{gs}) remains below the breakdown voltage of Zener diode Z₂, Z₂ remains in a non-conducting state. Under such conditions, the clamp circuit exhibits negligible influence and does not interfere with normal switching operation. However, when voltage overshoot and oscillation occur in the gate circuit typically during transistor turn-on or turn-off transitions-the extremely high switching speed (high di/dt, dv/dt) combined with inherent parasitic inductance in the PCB layout (particularly source parasitic inductance Ls) forms an LC resonant circuit with the transistor's input capacitance, resulting in high-frequency oscillation. Once the peak oscillation voltage exceeds the Zener voltage, Zener diode Z₂ undergoes reverse breakdown.

Upon breakdown of Z₂, an alternative discharge path is provided for the overshoot energy. The current follows the path:
Driver IC V_{OL}→Z₂→(R₄ξC₃)→Kelvin Source→GNDL.

After the Zener diode breakdown, the voltage across it stabilizes near the V_{z} value by R₄ is carefully configured. Thus, the maximum gate voltage is clamped to approximately V_{z}+I_{z}×R₄. Given that I_{z} is typically small, the additional voltage drop is often negligible. For instance, if V_{z} is 6.2 V, the gate voltage is limited to slightly above 6.2 V, which remains well below the typical gate withstand voltage ratings of GaN devices (e.g., ±9 V or +6 V/−3 V), thereby ensuring gate protection.

At the instant Z₂ begins conducting, capacitor C₃ starts to charge. Its primary functions include absorbing high-frequency energy, as it Z₂ can operate in reverse breakdown and stabilize voltage by using the characteristic that the current changes greatly but the voltage remains almost unchanged after breakdown, thereby enhancing voltage stability at the clamping node and mitigating excessive voltage fluctuation across Z₂.

Resistor R₄ serves to limit current, preventing excessive current during Z₂ breakdown and thus safeguarding both Z₂ and the driver IC. Additionally, it provides a discharge path for stored energy in capacitor C₃ once the oscillation peak subsides. The RC network formed by R₄ and C₃ determines the discharge time constant. Furthermore, R₄ increases the damping coefficient of the resonant circuit, effectively suppressing oscillation and promoting rapid decay.

The foregoing describes the structure and operating principle of the voltage clamp circuit. The circuit structure and operating principle of the negative voltage generation and control circuit will now be described. Referring again to FIG. 1, the negative voltage generation and control circuit 105 is electrically connected to a controller to receive at least one control signal and is further connected to the gate of the second GaN HEMT via the low-impedance Miller current path circuit 106. In summary, the negative voltage generation and control circuit 105 includes: a logic gate assembly having an input terminal configured to receive at least one control signal and an output terminal; a charge pump circuit electrically connected to the output terminal of the logic gate assembly and configured to generate a negative voltage; and a switching transistor configured to selectively apply the negative voltage to the gate of the first GaN HEMT based on an output from the logic gate assembly.

Specifically, as shown in FIG. 1, the negative voltage generation and control circuit 105 includes an AND gate U₃ having an input configured to receive a signal from the controller. An output of AND gate U₃ is connected to a gate of MOSFET S₂. Simultaneously, the output of AND gate U₃ is connected to an input of NOT gate U₄. An output of NOT gate U₄ is connected to a first terminal of a capacitor C₄. A second terminal of capacitor C₄ is connected to an anode of a ground-referenced diode D₄ in the low-impedance path. The output of AND gate U₃ is used to control a timing and an amplitude of the negative voltage application. NOT gate U₄, capacitor C₄, and diode D₄ collectively form a negative voltage generation circuit, wherein a negative voltage is applied from the anode of diode D₄ to the gate of the GaN HEMT via S₂ at a specific instance.

In the preferred embodiment, AND gate U₃ is a two-input AND gate. Its input signals are typically provided by the controller and include a drive signal for the lower transistor and an identification signal specifically configured to detect a switching state of the upper transistor. The output of the AND gate serves as a key control signal. NOT gate U₄ receives the output signal from AND gate U₃ and inverts it. Capacitor C₄ functions as an energy transfer and level-shifting component, while diode D₄ rectifies and isolates the generated negative voltage. MOSFET S₂ operates as a controlled electronic switch, directly controlled by the output of AND gate U₃, to determine when the generated negative voltage is applied to the gate.

The output of U₃ is directly connected to the gate of MOSFET S₂ and to the input of U₄. The output of U₄ is connected to the first terminal of capacitor C₄. The second terminal of capacitor C₄ is connected to the anode of diode D₄ and to the source terminal of S₂. The cathode of diode D₄ is connected to the reference ground. The source of S₂ is connected to the anode of D₄, and the drain of S₂ is connected to the anode of diode D₃ in the low-impedance Miller path, thereby providing a connection to the gate of the lower GaN HEMT Q₂.

Thus, the negative voltage generation and control circuit 105 is configured to actively apply a negative voltage to the gate of the GaN HEMT at a precisely controlled moment to counteract and cancel a positive voltage spike induced by positive crosstalk, thereby preventing spurious turn-on of the lower transistor Q₂ due to crosstalk.

FIG. 4 illustrates the operating principle of the negative voltage generation and control circuit, using positive crosstalk in the lower bridge arm as an example. When Q₁ is undergoing a turn-on transition while Q₂ is turned off, positive crosstalk occurs. The circuit, comprising C₄ and D₄ and controlled by the logic circuits U₃ and U₄, generates a negative voltage that is transferred to the gate of Q₂ through S₂. This action prevents the positive crosstalk-induced voltage spike from exceeding the threshold voltage of the GaN HEMT, thereby reducing the risk of spurious turn-on of Q₂.

Specifically, when the controller initiates turn-on of the upper transistor Q₁, it concurrently identifies that the lower transistor Q₂ remains in the off-state. This interval establishes a critical vulnerability period during which the lower transistor Q₂ is exposed to positive crosstalk interference.

The controller transmits specific signals to the AND gate (U₃), causing the output of U₃ to transition to a high logic level (e.g., 5 V or 3.3 V). The high-level output (V_{high}) from U₃ is immediately applied to the input of the NOT gate (U₄). U₄ inverts this signal, resulting in a low-level output (0 V).

At this moment, one terminal of capacitor C₄ (connected to the output of U₄) is pulled down to 0 V. Due to the inherent property of capacitors that prohibits an instantaneous change in voltage across their terminals, the voltage at the opposite terminal (connected to the anode of D₄) is forced to decrease by −V_{high} volts. Simultaneously, the high-level output from U₃ is applied to the gate of MOSFET S₂, turning S₂ on. The conduction of S₂ creates a low-impedance path between the anode of D₄ (the negative voltage point) and the gate of Q₂. As a result, this negative voltage of approximately −V_{high} is directly applied to the gate of the lower transistor Q₂.

Concurrently, due to the high-speed turn-on of the upper transistor Q₁, the high dv/dt induces a positive crosstalk current through capacitive coupling via the Miller capacitance (C_{gd2}), which attempts to elevate the gate voltage of Q₂.

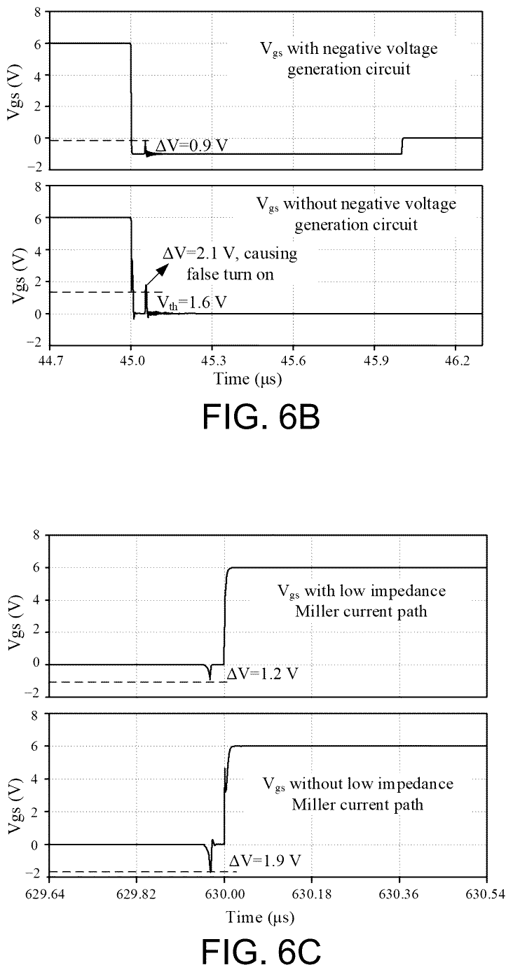

However, the gate of Q₂ has been proactively pulled to a negative voltage (e.g., −1 V) by the circuit. This negative voltage functions as a buffer or protective barrier. The positive crosstalk spike must first counteract this negative voltage (increasing from −1 V to 0 V) before it can approach the positive threshold voltage (e.g., +1.4 V) of the transistor. Consequently, the peak value of the gate voltage, superimposed with the negative bias, is significantly reduced, preventing it from reaching the turn-on threshold of Q₂ and thereby effectively avoiding spurious turn-on. As shown in FIG. 6B, the gate voltage is effectively reduced by ΔV_{gs} (0.9 V).

Upon completion of the turn-on process of the upper transistor Q₁, when it enters a stable conduction state, the dv/dt phenomenon diminishes, thereby concluding the period of susceptibility to positive crosstalk. The controller modifies the input signals, causing the output of the AND gate U₃ to return to a low logic level. The low-level output from U₃ results in the turning off of MOSFET S₂, which disconnects the path for applying the negative voltage. Simultaneously, it causes the output of the NOT gate U₄ to transition to a high logic level, thereby initiating the charging and resetting of capacitor C₄ in preparation for the subsequent operational cycle.

The foregoing describes the structure and operating principle of the negative voltage generation and control circuit. The circuit structure and operating principle of the low-impedance Miller current path 106 will now be described. Referring again to FIG. 1, the low-impedance Miller current path circuit 106 is electrically connected to the gate of the first GaN HEMT and is configured to provide a discharge path for Miller current to suppress negative crosstalk voltage spikes. The low-impedance Miller current path 106 includes a diode having a cathode connected to the gate of the GaN HEMT and a MOSFET having a drain connected to the anode of the diode.

Specifically, as shown in FIG. 1, the low-impedance Miller current path 106 includes a diode D₃ and a MOSFET S₂. Diode D₃ is connected in parallel with gate resistor R3, with its cathode connected to the gate of the GaN HEMT and its anode connected to the drain of S₂. The source of S₂ is connected to the anode of another diode D₄, and the cathode of diode D₄ is connected to the ground reference.

The gate of MOSFET S₂ is controlled by an output of AND gate U₃ within the negative voltage generation and control circuit, thereby synchronizing the switching state of S₂ with the operational state of the half-bridge.

The purpose of the low-impedance Miller current path is to provide a low-resistance discharge channel for the Miller current during occurrences of negative crosstalk, rapidly dissipating its energy to suppress negative voltage spikes at the gate and prevent breakdown or damage to the GaN HEMT due to excessive negative voltage.

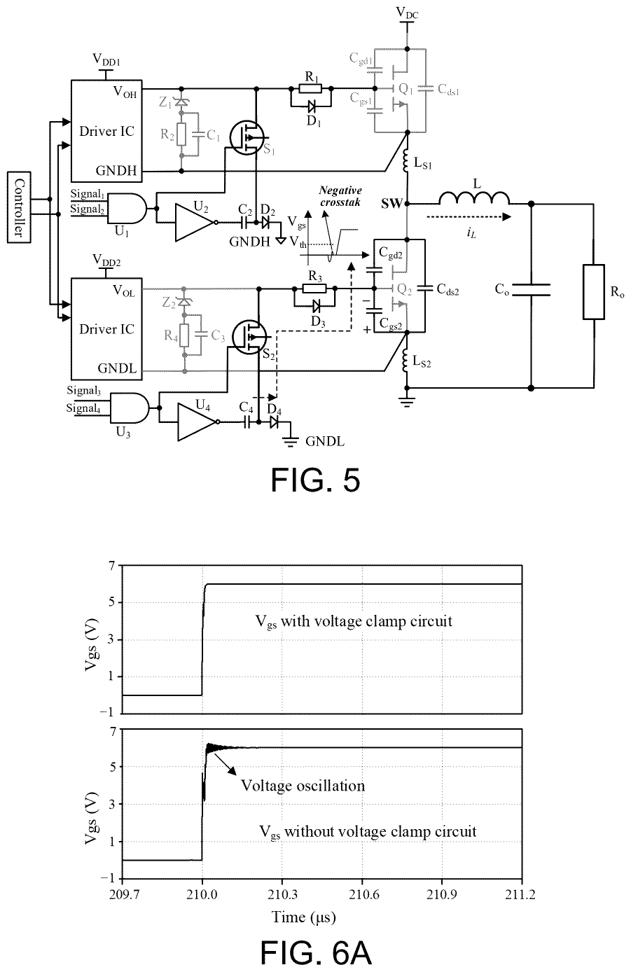

FIG. 5 illustrates the operating principle of the low-impedance Miller current path, using negative crosstalk in the lower bridge arm as an example. When Q₁ is undergoing a turn-off transition while Q₂ remains off, C_{ds2} and C_{gd2} of Q₂ discharge rapidly, causing the gate potential to decrease and generating negative crosstalk. The low-impedance Miller current path (comprising C₄, S₂, and D₃/R₃) becomes active and absorbs the crosstalk spike, thereby reducing the amplitude of the negative crosstalk.

Specifically, switching transistors-including MOSFETs and GaN HEMTs—exhibit an internal parasitic capacitance known as the Miller capacitance (C_{gd}), which is connected between the gate and drain. This capacitance is a key factor complicating switching behavior. During switching transitions, when the drain voltage undergoes rapid variation (dv/dt), a displacement current-referred to as the Miller current, calculated as i=C_{gd}×dv/dt—is generated through the Miller capacitance. This current may flow into or out of the gate, significantly compromising gate voltage stability.

For instance, when the upper transistor Q₁ turns off at high speed, its drain voltage—which corresponds to the drain voltage of the lower transistor Q₂—experiences a rapid increase, resulting in a high dv/dt. Consequently, the voltage at the switching node (SW) abruptly decreases to near 0.5V_{dc}. This high rate of voltage change (dv_{sw}/dt) couples through the gate-drain capacitance (C_{gd2}, or Miller capacitance) of the lower transistor Q₂, generating a displacement current.

This Miller current (Iₘᵢₗₗₑᵣ) must complete a circuit path. It flows from the gate of Q₂, through C_{gd2}, and into the SW node. In conventional drive circuits, this current is forced to return to the driver ground by passing through C_{ds2}.

According to Ohm's law (V=I×R), the current flowing through gate resistor R₃ produces a voltage drop across it. The direction of current flow results in a voltage drop that makes the gate voltage negative relative to ground. This phenomenon is the origin of the negative crosstalk voltage spike. If the magnitude of this negative spike exceeds the negative voltage rating of the GaN gate, it can cause gate degradation or failure, potentially leading to spurious turn-on of Q₂, bridge arm shoot-through, reduced system efficiency, or permanent device damage.

At this juncture, the negative voltage generation and control circuit 105 turns on MOSFET S₂ at the appropriate moment. Upon turn-on, S₂ establishes a low-impedance alternative path for the Miller current:
Diode D₄→MOSFET S₂ (on-state, low impedance)→Diode D₃→Gate of Q₂→C_{gd2} of Q₂→the SW node→C_{ds2} of Q₂→GNDL.

This low-resistance pathway diverts the majority of the Miller current, substantially reducing the current flowing through gate resistor R₃. The combined on-state resistance of D₃, S₂, and D₄ is significantly lower than the resistance value of R₃. Given the extremely low total impedance (Z_{low}) of this path, the resulting negative voltage drop, governed by V=I×Z_{low}, is minimized. Consequently, the amplitude of the negative voltage spike at the GaN gate is markedly reduced. As illustrated in FIG. 6C, the peak voltage is substantially lower than that observed in conventional solutions. The diverted energy is ultimately dissipated as heat across D₃, S₂, and D₄, thereby protecting the sensitive GaN gate structure.

Thus, the present disclosure effectively mitigates negative crosstalk by providing a low-impedance “current highway” that maintains hazardous negative voltage spikes within safe operational limits. This low-impedance Miller current path represents an advanced methodology for actively managing parasitic effects. In contrast to conventional designs that passively endure the Miller effect, this approach employs innovative circuit design to create a controlled “flood channel” for parasitic currents during critical switching events, safely diverting them away from the gate. This technology is essential for fully exploiting the high-frequency and high-efficiency benefits of GaN HEMTs while ensuring their stable and reliable operation.

A further technical advantage of the present invention lies in the synergistic operation and hardware reuse between the low-impedance Miller current path and the negative voltage generation circuit. MOSFET S₂ serves as a shared component in both circuits: During the positive crosstalk interval (when Q₁ is turned on), S₂ is conducting to apply a protective negative voltage to the gate; During the negative crosstalk interval (when Q₁ is turned off), S₂ remains conducting to provide the low-impedance discharge path for Miller current.

This dual functionality enables a single switching transistor to serve two distinct purposes, maximizing hardware utilization and contributing to a highly integrated overall design.

Additionally, diode D₃ ensures unidirectional current flow-only out of the gate during negative crosstalk events-preventing reverse current from interfering with normal switching operation. Diode D₄ also serves a dual role: it functions as a rectifier in the negative voltage charge pump and as part of the discharge path in the low-impedance Miller current circuit, further enhancing circuit efficiency and integration.

FIGS. 6A, 6B, and 6C demonstrate voltage overshoot and crosstalk suppression results comparing the present invention with conventional drive circuits. In FIG. 6A, the voltage clamp circuit maintains exceptional stability, regulating V_{gs} at 6 V with negligible oscillation and effectively suppressing parasitic resonance. FIG. 6B verifies the operation of the negative voltage generation circuit, where a voltage reduction of ΔV_{gs}=0.9 V effectively decreases sensitivity to crosstalk during switching transitions. In FIG. 6C, the implementation of the low-impedance path reduces the transient voltage drop by 36.8% compared to conventional drive circuits.

The present disclosure has been described and illustrated through specific embodiments, which are not intended to be limiting. These descriptions may not be exact, and artistic renderings may differ from actual devices due to manufacturing processes and tolerances. Other embodiments not explicitly described may exist, and modifications may be made to accommodate particular circumstances, materials, compositions, methods, or processes, all remaining within the scope of the appended claims. The methods described may involve operations performed in a specific sequence; however, these operations may be combined, subdivided, or reordered to form equivalent methods without departing from the teachings of the present disclosure. Therefore, unless otherwise specified, the order and grouping of operations are not limitations of the present invention.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A gate drive circuit for a half-bridge power module having a first GaN HEMT and a second GaN HEMT, the gate drive circuit comprising:
a voltage clamp circuit electrically connected to a gate resistor of the first GaN HEMT for suppressing a gate voltage overshoot at a gate of the first GaN HEMT;
a negative voltage generation and control circuit configured to generate a negative voltage and to apply the generated negative voltage to the gate of the first GaN HEMT to offset a positive crosstalk voltage spike at the gate of the first GaN HEMT; and
a low-impedance Miller current path circuit connected to the gate of the first GaN HEMT and configured to provide a discharge path for a Miller current to suppress a negative crosstalk voltage spike.

2. The gate drive circuit of claim 1, wherein:
the voltage clamp circuit is electrically connected between a gate control output terminal and a ground terminal of a driver IC, and further between the gate resistor and a Kelvin source of the first GaN HEMT, wherein the Kelvin source is directly connected to the ground terminal of the driver IC;
the negative voltage generation and control circuit is in communication with a signal source to receive at least one control signal and is operably connected to the gate of the first GaN HEMT via the low-impedance Miller current path circuit; and
the low-impedance Miller current path circuit is electrically connected to the gate of the first GaN HEMT to receive the Miller current and to the ground terminal to discharge the Miller current.

3. The gate drive circuit of claim 1, wherein the voltage clamp circuit comprises:
a Zener diode having a cathode electrically connected to a gate control output of a driver IC;
a first resistor having a first end connected to an anode of the Zener diode and a second end connected to a Kelvin source of the first GaN HEMT; and
a first capacitor connected in parallel with the first resistor.

4. The gate drive circuit of claim 3, wherein the gate resistor has a first end connected to the cathode of the Zener diode and a second end connected to the gate of the first GaN HEMT.

5. The gate drive circuit of claim 1, wherein the negative voltage generation and control circuit comprises:
an AND gate having a first input end and a second input end configured to receive control signals from a signal source;
a negative voltage generation circuit having an input end connected to an output end of the AND gate and configured to generate the negative voltage; and
a switching transistor having a gate connected to the output end of the AND gate, and configured to selectively apply the negative voltage to the gate of the first GaN HEMT.

6. The gate drive circuit of claim 5, wherein the negative voltage generation circuit comprises:
a NOT gate having an input end connected to the output end of the AND gate;
a second capacitor having a first end connected to an output end of the NOT gate; and
a first diode having an anode connected to a second end of the second capacitor and a cathode connected to the ground terminal.

7. The gate drive circuit of claim 5, wherein the switching transistor is a MOSFET having:
a gate connected to the output end of the AND gate,
a drain connected to the gate of the first GaN HEMT via the low-impedance Miller current path circuit, and
a source connected to the negative voltage generation circuit.

8. The gate drive circuit of claim 1, wherein the low-impedance Miller current path circuit comprises:
a second diode connected in parallel with the gate resistor of the first GaN HEMT, a cathode of the second diode being connected to the gate of the first GaN HEMT; and
a switching transistor configured to, when turned on, provide an electrical connection between an anode of the second diode and a ground.

9. The gate drive circuit of claim 8, wherein the switching transistor is controlled by the negative voltage generation and control circuit.

10. The gate drive circuit of claim 9, wherein the switching transistor is a MOSFET having:
a gate connected to an output end of an AND gate,
a drain connected to the gate resistor of the first GaN HEMT and the anode of the second diode, and
a source connected to the ground.

11. The gate drive circuit of claim 1, further comprising:
an additional voltage clamp circuit electrically connected to a gate resistor of the second GaN HEMT for suppressing a gate voltage overshoot at a gate of the second GaN HEMT;
an additional negative voltage generation and control circuit configured to generate a second negative voltage and to apply the generated second negative voltage to the gate of the second GaN HEMT to offset a positive crosstalk voltage spike at the gate of the second GaN HEMT; and
an additional low-impedance Miller current path circuit connected to the gate of the second GaN HEMT and configured to provide a discharge path for a Miller current to suppress a negative crosstalk voltage spike;
wherein the additional voltage clamp circuit has the same topology as the voltage clamp circuit; the additional negative voltage generation and control circuit has the same topology as the negative voltage generation and control circuit; the additional low-impedance Miller current path circuit has the same topology as the low-impedance Miller current path circuit.

12. The gate drive circuit according to claim 3, wherein the Zener diode is a diode with an ultra-short reverse recovery time of less than 0.1 μs.

13. The gate drive circuit according to claim 1, wherein each of the first GaN HEMT and the second GaN HEMT is an E-mode GaN HEMT.

14. The gate drive circuit according to claim 3, wherein the first capacitor has a capacitance value in a range of 1−100 nF.

15. The gate drive circuit according to claim 4, wherein the gate resistor has a resistance value in a range of 1−100Ω.

16. The gate drive circuit according to claim 13, wherein the E-mode GaN HEMT has a rated current higher than a current flowing through the gate drive circuit during a crosstalk event, wherein the current comprises 0.1 A.

17. The gate drive circuit according to claim 5, wherein the AND gate is a high-frequency operating component operating at 5 MHz.

18. The gate drive circuit according to claim 6, wherein the NOT gate is a high-frequency operating component operating at 5 MHz.

19. The gate drive circuit according to claim 7, wherein the MOSFET is a high-frequency operating positive metal oxide semiconductor (PMOS) or negative metal oxide semiconductor (NMOS) operating at 5 MHz, or can be replaced by silicon carbide (SiC) or GaN.

20. The gate drive circuit according to claim 10, wherein the MOSFET is a high-frequency operating positive metal oxide semiconductor (PMOS) or negative metal oxide semiconductor (NMOS) operating at 5 MHz, or can be replaced by silicon carbide (SiC) or GaN.
